(19) United States
(12) Patent Application Publication
(10) Pub. No.: US 2015/0309546 A1
(43) Pub. Date: Oct. 29, 2015

(54) Computing Devices

(71) Applicant: Cybula Ltd., Yorkshire (GB)

(72) Inventor: James Austin, Yorkshire (GB)

(21) Appl. No.: 14/441,593

(22) PCT Filed: Nov. 8, 2013
(86) PCT No.: PCT/GB2013/052945

§ 371 Date: May 8, 2015

(30) Foreign Application Priority Data
Nov. 8, 2012 (GB) 1220117.4

(51) Int. Cl. G06F 1/26; G06F 1/20; H05K 7/20; G06F 1/18

(52) U.S. Cl. CPC G06F 1/26; G06F 1/181; G06F 1/20; H05K 7/20236; H05K 7/20272; H05K 7/20254

(57) ABSTRACT

Two computing elements (1) are located in a tank (2) containing impure water (3), which acts as a coolant. Two electrodes (4) receive electrical power from terminals (5) and supply an electric current to the water (3). Each computing element (1) comprises a housing (11) of generally cuboid shape. Each of the corners of the housing (11) is chamfered such that each of the six cuboid sides has a plane facet (12) and chamfered facets (13, 14). Electrodes (16) are provided in pairs on opposite facets (12). A potential difference is applied to the electrodes (4) and thus between electrodes (16). The electrical conductivity of the water (3) provides current flow through the water to power the computing elements (1), each of which has relatively low power consumption. Communication between computing elements (1) is also effected via the electrodes (16).

The present invention relates to computing devices and is concerned particularly with computing devices that comprise a collection of individual computing elements that intercommunicate and receive power by wireless methods.

Such computing devices are disclosed in WO 03/023583, containing novel proposals for computing devices that can be constructed simply and of a size that can be varied quickly. However, a continuing challenge is to find simple and robust ways to achieve wireless communication and power transmission for the individual computing elements.

Preferred embodiments of the present invention aim to answer this challenge.

According to one aspect of the present invention, there is provided a computing device that comprises a collection of individual computing elements that both intercommunicate and receive power by wireless methods, wherein each of the computing elements comprises a respective housing that contains a processing element, all of the housings are immersed in an electrically conductive liquid to which electrical power is supplied, each of the housings carries mutually spaced electrodes that contact the liquid to receive electrical power, and communication between the computing elements is effected by signal transmission through the liquid.

Preferably, the liquid is impure water.

Preferably, at least some of said electrodes are used for both communication and power transfer.

Preferably, said electrodes are platinum coated.

Preferably, said electrodes comprise titanium.

Preferably, said housings are provided with projections to space the housings from one another, thereby to allow the flow of liquid to the electrodes.

Preferably, each of said housings is generally of cuboid shape.

Preferably, each of said housings has chamfered corners to facilitate the flow of liquid between the housings.

Preferably, the computing elements are placed in a container in a non-organised fashion, the container containing the liquid.

A computing device according to any of the preceding aspects of the invention may further comprise a heat-exchanger and means for circulating the liquid through the tank and through the heat-exchanger, such that the liquid serves as a coolant for the computing elements.

For a better understanding of the invention, and to show how embodiments of the same may be carried into effect, reference will now be made, by way of example, to the accompanying diagrammatic drawings, in which:

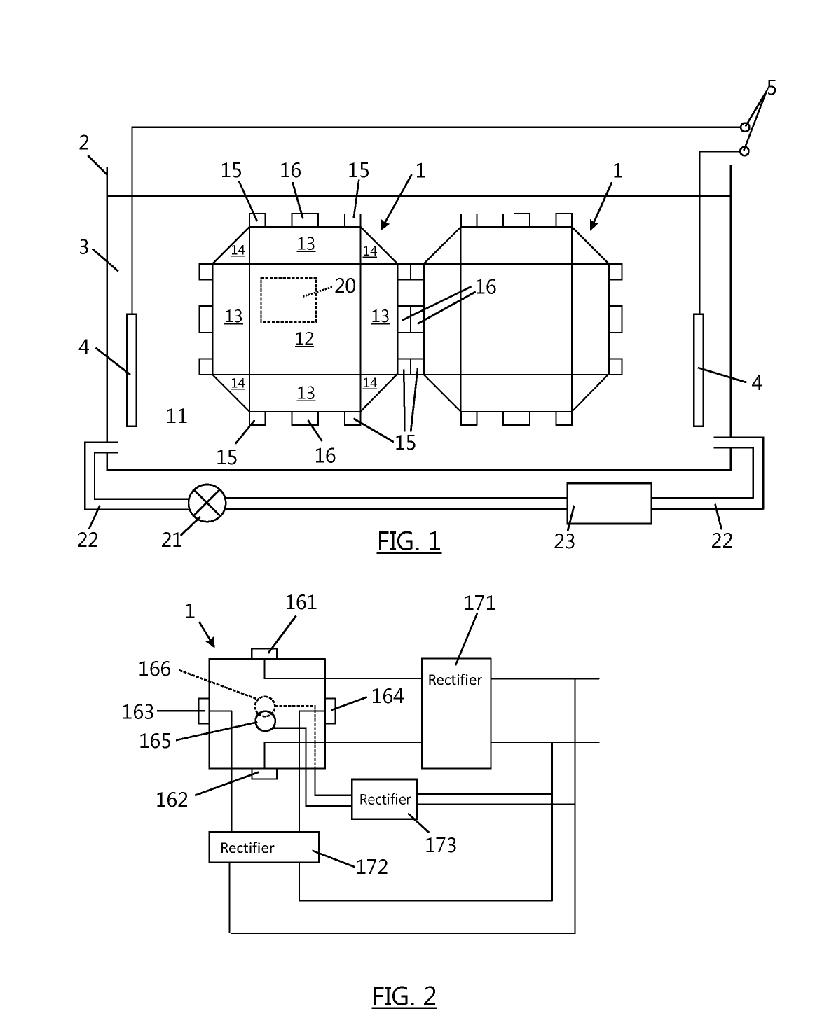

FIG. 1 shows two computing elements immersed in a tank of water, in side elevation; and

FIG. 2 illustrates power rectification in a computing element.

In the figures, like references denote like or corresponding parts.

It is to be understood that the various features that are described in the following and/or illustrated in the drawings are preferred but not essential. Combinations of features described and/or illustrated are not considered to be the only possible combinations. Unless stated to the contrary, individual features may be omitted, varied or combined in different combinations, where practical.

FIG. 1 shows two computing elements 1 that are located in a tank 2 containing water 3. A pump 21 pumps the water 3 around a circuit 22 and through a heat exchanger 23, so that that the water acts as a coolant for the computing elements 1. Two electrodes 4 receive electrical power from terminals 5 and supply an electric current to the water 3. The water is impure and therefore has significant electrical conductivity. The level of impurity does not have to be high; for example, tap water may suffice in many regions.

Each computing element 1 comprises a housing 11 of generally cuboid shape—that is, having six mutually orthogonal sides, each as shown in elevation in FIG. 1. Each of the corners of the housing 11 is chamfered, such that each of the six sides has nine facets, comprising a plane facet 12, four chamfered facets 13 each extending along a respective side of the plane facet 12, and four chamfered facets 14 each extending between three of the chamfered facets 13. Such a shape of housings 11 facilitates positioning of the computing elements 1 in any orientation.

Each of the housings 11 is provided with a plurality of protrusions 15 that engage with other housings 11 to afford clearance between the respective housings. Electrodes 16 are provided on the plane facets 12 and, in this example, are arranged in pairs on opposite facets 12.

FIG. 2 shows diagrammatically one computing element 1 in which electrodes 161 and 162 are disposed on opposite faces of a cuboid. The outputs of the electrodes 161 and 162 are fed to a rectifier 171 Similarly, another pair of electrodes 163, 164 is disposed on other, opposite faces of the cuboid and their outputs are fed to a rectifier 172. In a similar manner, a third pair of electrodes 165, 166 is provided on the remaining faces of the cuboid and their outputs fed to a rectifier 173. The outputs of the rectifiers 171, 172, 173 are summed.

To return to FIG. 1, a potential difference is applied to the terminals 5 to establish a corresponding potential difference between the electrodes 4 that are immersed in the water 3. Accordingly, with the electrodes 16 of each computing element 1 connected as in the example illustrated in FIG. 2, potential differences in the water 3 are established across each pair of electrodes 16 and summed via rectifiers such as the rectifiers 171 to 173. The summed output from the rectifiers provides sufficient power to drive data processing elements 20 within the computing elements 1. The rectifiers 171 to 173 ensure uniform polarity from the various pairs of electrodes 16.

The electrical conductivity of the water is sufficient to provide adequate current flow through the water to power the computing elements 1, each of which has relatively low power consumption.

Communication between computing elements 1 is also effected via the electrodes 16. In one experiment, with a configuration as illustrated in FIG. 1, a potential difference of about 20 volts was applied to the electrodes 4 via terminals 5. Rectified power from rectifiers such as 171-173 was regulated to a maximum of about 3 volts. It was found that reliable power on both computing elements 1 was generated at any placement of the feed electrodes 4 in the tank 2 Communication between computing elements 1 was then effected by generating a signal at over 100 kHz in an oscillator in one of the computing elements 1 and transmitting it into the water 3 via the electrodes 16. The transmitted signal was received on the electrodes 16 of the other computing element 1, in which an amplifier boosted the signal to logic levels, via a Schmitt trigger. Reliable and clean signals were obtained in both directions between computing elements 1.

In a similar manner to the power transmission arrangement, all six electrodes 16 on each computing element 1 were used for communication.

The experiment demonstrated that both communications and power transfer may take place to and from the computing elements 1 via common electrodes 16. Two-way transmissions on a single circuit may be enabled using many protocols, a simple example being time division multiplexing.

The shape of the housings 11 has been found to be very practical, as the computing elements 1 tend to self-align with each other if dropped in a container. In this connection, the reader is referred to our earlier publication WO 03/023583, which explains how a computing device may be constructed simply by pouring a plurality of computing elements into a container, the computing elements intercommunicating and receiving power by wireless methods. In the context of the present specification, although just two computing elements 1 have been shown in FIG. 1 to illustrate the principles of the illustrated embodiment, any number of computing elements 1 may be poured into a container containing impure water or another electrically conductive liquid, to intercommunicate and receive power—for example, as described herein. Pouring the computing elements 1 into the container results in the computing elements being placed in the container in a non-organised fashion —that is, no positive step are taken to organise the orientation and juxtaposition of the individual computing elements 1.

The chamfered corners allow water to flow easily though an array of computing elements 1. The protrusions 15 assist the flow of water to the electrodes 16. As illustrated in FIG. 1, it is possible for metal to metal contact to take place between electrodes 16, which allows communications to be very efficient. However, communications can nevertheless occur via the water when a direct connection is not present. Metal to metal contact between some of the electrodes 16 does not seem to affect the power transfer process.

In connection with the use of impure water as a conductor for communications, water has a high resistance in its pure form and low resistance in its impure form. For example, pure water is typically 20 M ohms per cm, whereas drinking water is typically 20-300 ohms per meter. This makes drinking water potentially attractive for short range electrical communications. Any close electrodes can communicate; the resistance to further off electrodes reduces crosstalk.

In order to minimise electro-deposition and erosion under the action of current in the water 3, all of the electrodes 4 and 16 are preferably of platinum-coated titanium. The platinum is very stable, and only needs to be thinly applied to the electrodes. Alternative electrode materials may be used, so long as they do not erode under the action of an applied potential.

Although water is used in the above examples, alternative electrically conductive liquids may be used. Any electrolyte might be suitable, so long as it does not react adversely with the computing elements 1. Pure water could theoretically be used, but may not afford sufficient electrical conductivity. In the context of this specification, the term ‘liquid’ may include a gel, although gels may be less practical as coolants.

Computing elements 1 may be of shapes other than cuboids. For example, they may be spherical or spheroidal.

In this specification, the verb “comprise” has its normal dictionary meaning, to denote non-exclusive inclusion. That is, use of the word “comprise” (or any of its derivatives) to include one feature or more, does not exclude the possibility of also including further features. The word “preferable” (or any of its derivatives) indicates one feature or more that is preferred but not essential

The reader's attention is directed to all and any priority documents identified in connection with this application and to all and any papers and documents which are filed concurrently with or previous to this specification in connection with this application and which are open to public inspection with this specification, and the contents of all such papers and documents are incorporated herein by reference.

All or any of the features disclosed in this specification (including any accompanying claims, abstract and drawings), and/or all or any of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. A computing device that comprises a collection of individual computing elements that both intercommunicate and receive power by wireless methods, wherein each of the computing elements comprises a respective housing that contains a processing element, all of the housings are immersed in an electrically conductive liquid to which electrical power is supplied, each of the housings carries mutually spaced electrodes that contact the liquid to receive electrical power, and communication between the computing elements is effected by signal transmission through the liquid.

2. A computing device according to claim 1, wherein the liquid is impure water.

3. A computing device according to claim 1, wherein at least some of said electrodes are used for both communication and power transfer.

4. A computing device according to claim 1, wherein said electrodes are platinum coated.

5. A computing device according to claim 1, wherein said electrodes comprise titanium.

6. A computing device according to claim 1, wherein said housings are provided with projections to space the housings from one another, thereby to allow the flow of liquid to the electrodes.

7. A computing device according to claim 1, wherein each of said housings is generally of cuboid shape.

8. A computing device according to claim 7, wherein each of said housings has chamfered corners to facilitate the flow of liquid between the housings.

9. A computing device according to claim 1, wherein the computing elements are placed in a container in a non-organised fashion, the container containing the liquid.

10. A computing device according to claim 1, further comprising a heat-exchanger and means for circulating the liquid through the tank and through the heat-exchanger, such that the liquid serves as a coolant for the computing elements.

11. (canceled)
